(19) United States
(12) Patent Application Publication
(10) Pub. No.: US 2026/0123283 A1
(43) Pub. Date: Apr. 30, 2026

(54) THERMOELECTRIC GENERATOR SUBSTRATE AND THERMOELECTRIC GENERATOR

(71) Applicant: WASEDA UNIVERSITY, Tokyo (JP)

(72) Inventors: Eiji IWASE, Tokyo (JP); Atsuki OGUCHI, Tokyo (JP); Shingo TERASHIMA, Tokyo (JP)

(21) Appl. No.: 19/372,648

(22) Filed: Oct. 29, 2025

(30) Foreign Application Priority Data
Oct. 30, 2024 (JP) 2024-190936

(51) Int. Cl. H10N 10/17

(52) U.S. Cl. CPC H10N 10/17

(57) ABSTRACT

A thermoelectric generator substrate includes: a flexible substrate including an insulating base material and a metal layer; and a cell substrate portion, wherein the cell substrate portion includes a strip-shaped first beam portion, a strip-shaped first leg portion whose one end is coupled to one end of the first beam portion and extends toward a center of the first beam portion, a strip-shaped second leg portion whose one end is coupled to the other end of the first beam portion and extends toward the center of the first beam portion, a first contact portion coupled to the other end of the first leg portion and in contact with a heat source, and a second contact portion coupled to the other end of the second leg portion and in contact with the heat source, and the first leg portion and the second leg portion are configured to deform and erect by widening an interval between the first contact portion and the second contact portion.

### DESCRIPTION

### CROSS REFERENCE TO RELATED APPLICATIONS

This application claims the benefit of foreign priority to Japanese Patent Application No. 2024-190936, filed on October 30, 2024, which is incorporated by reference in its entirety.

### TECHNICAL FIELD

The present invention relates to a thermoelectric generator substrate and a thermoelectric generator.

### BACKGROUND ART

A cut sheet type (Kirigami-type) thermoelectric generator (TEG) is known in which a sheet-shaped wiring substrate is cut and deformed into a three-dimensional structure. The inventors have proposed a cut sheet type thermoelectric generator in which a pair of L-shaped cuts are formed in a rectangular wiring substrate with two-fold symmetry to form a pair of leg portions and a beam portion (see PTL 1). In the thermoelectric generator of PTL 1, by moving tip ends of the pair of leg portions that are in contact with a heat source surface closer to each other, the pair of leg portions are erected diagonally upward from the heat source surface, and the beam portion is floated from the heat source surface to form a three-dimensional structure with a floating posture. The thermoelectric generator includes the pair of leg portions each equipped with a thermoelectric element that generates electric power by a temperature difference. The beam portion serving as a heat dissipation surface can be sufficiently separated from the heat source surface, and thus a high power generation efficiency can be obtained.

A cut sheet type thermoelectric generator is known in which a rectangular wiring substrate is formed with a plurality of cuts arranged in a zigzag manner, and the wiring substrate is extended such that the cuts each have a substantially rhombic opening, whereby the wiring substrate is deformed into a mesh shape and is made three-dimensional (see NPL 1).

### Citation List

### Patent Literature

PTL 1: JP2022-186538A

PTL 2: JP2023-051302A

### Non Patent Literature

NPL 1: Zhanpeng Guo, et al. "Kirigami-Based Stretchable, Deformable, Ultralight Thin-Film Thermoelectric Generator for BodyNET Application, " Advanced Energy Materials, vol. 12, 2102993, 2021.

### SUMMARY OF THE INVENTION

### Technical Problem

In general, a voltage generated by a pair of thermoelectric elements is small, and thus a large number of thermoelectric elements are arrayed to constitute a thermoelectric generator. In the thermoelectric generator of PTL 1, a plurality of unit configurations each including the one beam portion and the pair of leg portions as described above are made to be continuous, whereby a large number of thermoelectric elements are arrayed. However, in such a structure, when a large number of thermoelectric elements are made three-dimensional as the thermoelectric generator, it is necessary to deform the unit configurations one by one, and there is a problem that the process becomes complicated. On the other hand, the thermoelectric generator of NPL 1 can be easily made three-dimensional by simply stretching the entire wiring substrate, but there is a problem of low power generation efficiency. This is because a distance from the heat source surface of a portion to be the heat dissipation surface is not increased in a state in which the thermoelectric generator is made three-dimensional, and a contact portion of the heat source surface and a portion farthest from the heat source surface are linear.

The present invention has been made in view of the above circumstances, and an object thereof is to provide a thermoelectric generator substrate and a thermoelectric generator that can improve power generation efficiency and can be easily made three-dimensional.

### Solution to Problem

A thermoelectric generator substrate of the present invention is a thermoelectric generator substrate including: a flexible substrate including a sheet-shaped insulating base material and a metal layer formed on one surface of the base material; and a cell substrate portion formed on the flexible substrate. The cell substrate portion includes a strip-shaped first beam portion, a strip-shaped first leg portion whose one end is coupled to one end of the first beam portion in a width direction and extends parallel to the first beam portion toward a center of the first beam portion, a strip-shaped second leg portion whose one end is coupled to the other end of the first beam portion in the width direction and extends parallel to the first beam portion toward the center of the first beam portion, a first contact portion coupled to the other end of the first leg portion in the width direction on a side opposite to the first beam portion and in contact with a heat source, and a second contact portion coupled to the other end of the second leg portion in the width direction on a side opposite to the first beam portion and in contact with the heat source, and the first leg portion and the second leg portion are configured to deform and erect such that the one end of the first leg portion and the one end of the second leg portion move in a direction away from the first contact portion and the second contact portion together with the first beam portion in a thickness direction of the substrate by widening an interval between the first contact portion and the second contact portion.

The thermoelectric generator of the present invention includes the thermoelectric generator substrate in which a plurality of the cell substrate portions are continuously formed, and a thermoelectric element.

### Advantageous Effects of the Invention

According to the present invention, it is possible to increase a contact area with the heat source to improve a power generation efficiency, and the first leg portion and the second leg portion of the cell substrate portion are erected and made three-dimensional by the pulling of the thermoelectric generator substrate, and thus whether there is one cell substrate portion as a unit configuration or a plurality of continuous cell substrate portions, the plurality of cell substrate portions can be collectively made three-dimensional at once.

### BRIEF DESCRIPTION OF DRAWINGS

FIG. 1 is a perspective view illustrating a three-dimensional thermoelectric generator according to an embodiment.

FIG. 2 is an exploded perspective view illustrating a power generation cell in a flat plate shape.

FIG. 3 is a perspective view illustrating the three-dimensional power generation cell.

FIG. 4 is a plan view illustrating the thermoelectric generator in a flat plate state in which power generation cells are arranged in three rows and three columns.

FIG. 5 is a circuit diagram illustrating a circuit of the thermoelectric generator.

FIG. 6 is a perspective view illustrating an example of a power generation cell in which two unit circuits are formed.

FIG. 7 is a perspective view illustrating an example of a power generation cell in which two unit circuits are connected in series.

FIG. 8 is a perspective view illustrating another example of a power generation cell in which two unit circuits are formed.

FIG. 9 is a plan view illustrating a thermoelectric generator in a flat plate state in which 18 unit circuits are connected in series using 9 power generation cells.

FIG. 10 is a circuit diagram illustrating a circuit of the thermoelectric generator in FIG. 9.

FIG. 11 is a plan view illustrating a thermoelectric generator in a flat plate state in which 15 unit circuits are connected in series using 9 power generation cells.

FIG. 12 is a circuit diagram illustrating a circuit of the thermoelectric generator in FIG. 11.

FIG. 13 is a perspective view illustrating a power generation cell having a two-leg configuration.

FIG. 14 is a plan view illustrating a cell substrate portion of the power generation cell in FIG. 13.

FIG. 15 is a perspective view illustrating another example of a power generation cell having a four-leg configuration.

FIG. 16 is a plan view illustrating a cell substrate portion of the power generation cell in FIG. 15.

FIG. 17 is a graph illustrating a result of measuring heights of both ends of each beam portion when a thermoelectric generator substrate including five power generation cells is made three-dimensional.

FIG. 18 is a graph illustrating a result of measuring a power generation capacity of one power generation cell.

### DESCRIPTION OF EMBODIMENTS

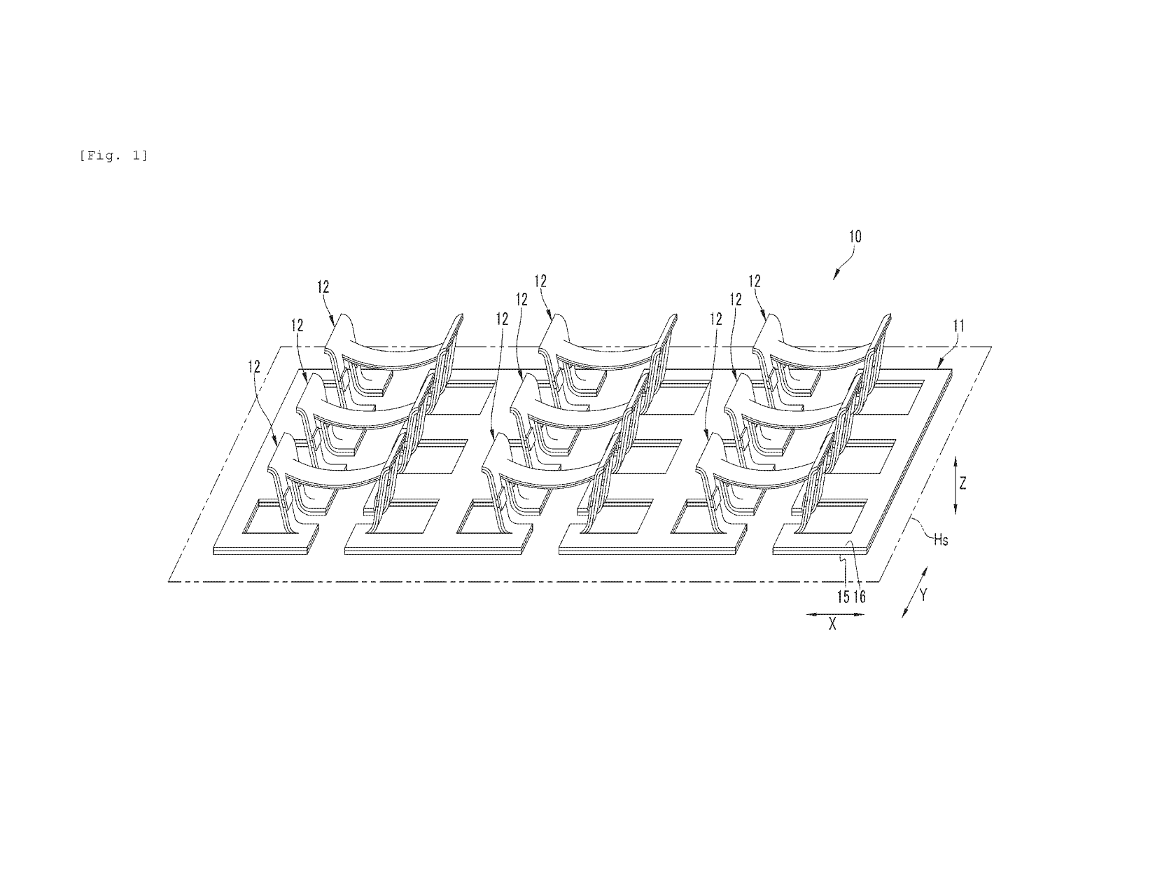

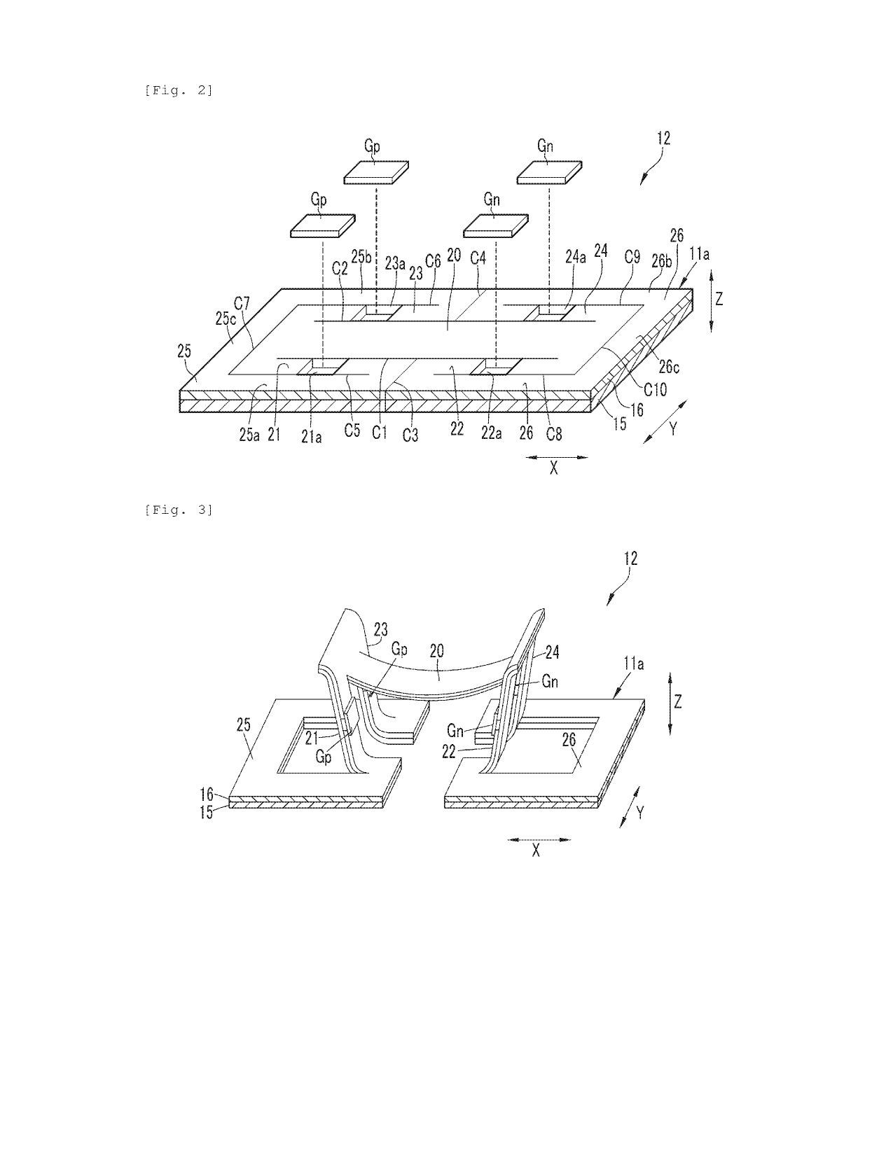

In FIG. 1, a thermoelectric generator 10 is used by being attached to a surface Hs of a heat source (hereinafter, referred to as a heat source surface) such as an engine, a pipe, and an electronic device. The thermoelectric generator 10 includes a plurality of thermoelectric elements Gp and Gn (see FIG. 2) fixed to a flat plate-shaped wiring substrate 11, and is attached to the heat source surface Hs in a state of being erected from a flat plate shape into a three-dimensional shape. The thermoelectric generator 10 in this example includes a plurality of power generation cells 12. The power generation cell 12 is a unit configuration of the thermoelectric generator 10, and in this example, the power generation cells 12 are provided in three rows and three columns.

Hereinafter, the description will be given assuming that the thermoelectric generator 10 is attached to the heat source surface Hs, which is a planar heat source, but a posture or the like of the thermoelectric generator 10 with respect to the heat source surface Hs is not limited. In addition, the heat source surface Hs is described as a flat surface as an example, but the heat source surface Hs to which the thermoelectric generator 10 is attached is not limited to a flat surface.

The wiring substrate 11 as a thermoelectric generator substrate has a configuration in which a metal layer 16 is formed on an upper surface of a base film 15 as a sheet-shaped insulating base material, and has flexibility. The base film 15 is made of an insulating resin, in this example, polyimide. In this example, the base film 15 has flexibility, and the flexibility of the wiring substrate 11 is mainly due to the flexibility of the base film 15. The metal layer 16 is made of a metal having high thermal conductivity and electrical conductivity, in this example, copper (Cu).

The base film 15 may have an insulating property at least on a surface on a metal layer 16 side. In addition, the base film 15 may be made of a material other than the resin, or may have a configuration including a plurality of layers made of different materials. In addition, heat from the heat source surface Hs is transferred to the metal layer 16 via the base film 15, and thus the base film 15 preferably has high thermal conductivity. The metal layer 16 may be a material having high thermal conductivity and electrical conductivity, and may be aluminum (Al), gold (Au), or the like.

In FIG. 2, one of the power generation cells 12 includes a cell substrate portion 11a formed on the wiring substrate 11 and two thermoelectric elements Gp and Gn. FIG. 2 illustrates the flat plate-shaped cell substrate portion 11a in which the wiring substrate 11 is not made three-dimensional.

The cell substrate portion 11a is formed with a beam portion 20, a first leg portion 21 to a fourth leg portion 24, a first contact portion 25, and a second contact portion 26. The beam portion 20, the first leg portion 21 to the fourth leg portion 24, the first contact portion 25, and the second contact portion 26 are formed by forming straight cut lines C1 to C10 on the rectangular cell substrate portion 11a according to shapes thereof. In addition, the first leg portion 21 to the fourth leg portion 24 are formed with insulating regions 21a to 24a, respectively. In this example, the cell substrate portion 11a is provided with the metal layer 16 on an entire surface except for the insulating regions 21a to 24a.

The cut lines C1 to C10 are used to separate adjacent regions of the cell substrate portion 11a, with the cut lines C1 to C10 interposed therebetween. A method of forming the cut lines C1 to C10 is not particularly limited, and a method corresponding to the materials of the base film 15 and the metal layer 16 may be used. For example, the cut lines C1 to C10 can be formed by laser processing. At the time of manufacturing, the cut lines C1 to C10 may not be in a state in which the adjacent regions with the cut lines C1 to C10 interposed therebetween are completely separated. For example, when the thermoelectric generator 10 is mounted on the heat source surface Hs, that is, when the thermoelectric generator 10 is made three-dimensional, the cut lines C1 to C10 may be, for example, groove-shaped cuts that allow easy separation at those portions.

The beam portion 20 is formed in a strip shape extending in a direction parallel to one side of the cell substrate portion 11a with a predetermined width at a center of the cell substrate portion 11a by the cut lines C1 and C2. When the power generation cell 12 is made three-dimensional, the beam portion 20 is raised to a position higher than the first contact portion 25 and the second contact portion 26, and is in a state of floating above the heat source surface Hs. The beam portion 20 functions as a heat radiation plate in the power generation cell 12.

In the following description, a direction (longitudinal direction in this example) connecting one end and the other end of the beam portion 20 in the cell substrate portion 11a formed in a flat plate shape is referred to as an X direction, a width direction of the beam portion 20 orthogonal to the X direction is referred to as a Y direction, and a thickness direction of the cell substrate portion 11a is referred to as a Z direction. In this example, the beam portion 20 has a strip shape that is long in the X direction. The beam portion 20 may have a width larger than a length in the X direction.

The first leg portion 21 and the third leg portion 23 are formed at one end side of the beam portion 20 in the X direction (left side in FIG. 2) with the beam portion 20 interposed therebetween, and the second leg portion 22 and the fourth leg portion 24 are formed at the other end side of the beam portion 20 (right side in FIG. 2) with the beam portion 20 interposed therebetween. In the width direction of the beam portion 20, the first leg portion 21 and the second leg portion 22 are arranged on one side (front side in FIG. 2), and the third leg portion 23 and the fourth leg portion 24 are arranged on the other side (rear side in FIG. 2). In this example, each of the first leg portion 21 to the fourth leg portion 24 has a strip shape and has a length that is 1/2 of the length of the beam portion 20.

The first leg portion 21 has one end (tip end) that is coupled to the one end of the beam portion 20 in the Y direction, and extends in a strip shape parallel to the beam portion 20 toward a center in the X direction of the cell substrate portion 11a (beam portion 20). Therefore, the cut line C1 that separates the beam portion 20 from the first leg portion 21 and the second leg portion 22 in the Y direction is not formed at a boundary between the one end of the beam portion 20 and the one end of the first leg portion 21. Accordingly, the one end of the beam portion 20 and the one end of the first leg portion 21 are coupled without being separated. The coupling between the end portions means that side edges of the end portions are coupled and integrated.

The second leg portion 22 is located on an extension line of the first leg portion 21, has one end (tip end) that is coupled to the other end of the beam portion 20 in the Y direction, and extends in a strip shape parallel to the beam portion 20 toward the center of the cell substrate portion 11a (beam portion 20) in the X direction. Therefore, the cut line C1 is not formed at a boundary between the other end of the beam portion 20 and the one end of the second leg portion 22. Accordingly, the other end of the beam portion 20 and the one end of the second leg portion 22 are coupled without being separated. The other end (base end) of the first leg portion 21 and the other end (base end) of the second leg portion 22 are separated by the cut line C3 formed in the Y direction.

The third leg portion 23 is similar to the first leg portion 21, but one end (tip end) thereof is coupled to the one end of the beam portion 20 on a side opposite to the first leg portion 21 in the Y direction. In addition, the fourth leg portion 24 is located on an extension line of the third leg portion 23. The fourth leg portion 24 is similar to the second leg portion 22, but one end (tip end) thereof is coupled to the other end of the beam portion 20 on a side opposite to the second leg portion 22 in the Y direction. That is, the one end of the beam portion 20 and the one end of the third leg portion 23 are not separated by the cut line C2, and the other end of the beam portion 20 and the one end of the fourth leg portion 24 are not separated by the cut line C2. The other end (base end) of the third leg portion 23 and the other end (base end) of the fourth leg portion 24 are separated by the cut line C4 formed in the width direction.

As can be seen from the above description, the cut line C1 is formed at boundaries between the beam portion 20, and the first leg portion 21 and the second leg portion 22 except for boundaries between the one end of the beam portion 20 and the other end of the first leg portion 21 and the other end of the second leg portion 22. The cut line C2 is formed at boundaries between the beam portion 20, and the third leg portion 23 and the fourth leg portion 24 except for boundaries between the one end of the beam portion 20 and the other end of the third leg portion 23 and the other end of the fourth leg portion 24.

The first leg portion 21 to the fourth leg portion 24 are erected such that the one ends thereof are raised by increasing the interval between the other ends of the first leg portion 21 and the third leg portion 23 and the other ends of the second leg portion 22 and the fourth leg portion 24, thereby floating the beam portion 20. This is because the one ends of the first leg portion 21 and the third leg portion 23, and the second leg portion 22 and the fourth leg portion 24 are coupled to both ends of the beam portion 20 having a certain length.

The first contact portion 25 and the second contact portion 26 are in surface contact with the heat source surface Hs. The first contact portion 25 is formed in a "U" shape, and includes a strip-shaped first region 25a that is disposed outside the first leg portion 21 (on a side opposite to the beam portion 20) and extends parallel to the first leg portion 21 toward the one end of the first leg portion 21, a strip-shaped second region 25b that is disposed outside the third leg portion 23 and extends parallel to the third leg portion 23 toward the one end of the first leg portion 21, and a strip-shaped third region 25c that couples the first region 25a and the second region 25b and extends in the Y direction.

One end (one end of the first contact portion 25) of the first region 25a is coupled to the other end of the first leg portion 21 in the Y direction. Similarly, one end (other end of the first contact portion 25) of the second region 25b is coupled to the other end of the third leg portion 23 in the Y direction. Therefore, the cut line C5 that separates the first leg portion 21 and the first region 25a in the Y direction is formed at a boundary between the first leg portion 21 and the first contact portion 25 except for a boundary between the other end of the first leg portion 21 and the one end of the first contact portion 25. In addition, the cut line C6 that separates the third leg portion 23 and the second region 25b in the Y direction is formed at a boundary between the third leg portion 23 and the first contact portion 25 except for a boundary between the other end of the third leg portion 23 and the one end of the second region 25b. Accordingly, the other end of the first leg portion 21 and the one end of the first contact portion 25, and the other end of the third leg portion 23 and the other end of the first contact portion 25 are coupled without being separated.

The third region 25c is formed outside the one end of each of the first leg portion 21, the beam portion 20, and the third leg portion 23 in the X direction and formed in a strip shape extending in the Y direction. The cut line C7 is formed at a boundary extending in the Y direction between the third region 25c and the one end of each of the first leg portion 21, the beam portion 20, and the third leg portion 23. Therefore, the cut lines C5 to C7 form one cut line in a "U" shape.

Similarly to the first contact portion 25, the second contact portion 26 is formed in a "U" shape, and includes a strip-shaped first region 26a that is disposed outside the second leg portion 22 (on the side opposite to the beam portion 20) and extends parallel to the second leg portion 22 toward the one end of the second leg portion 22, a strip-shaped second region 26b that is disposed outside the fourth leg portion 24 and extends parallel to the fourth leg portion 24 toward the one end of the fourth leg portion 24, and a strip-shaped third region 26c that couples the first region 26a and the second region 26b and extends in the Y direction.

One end of the first region 26a (one end of the second contact portion 26) is coupled to the other end of the second leg portion 22 in the Y direction, and one end of the second region 26b (other end of the second contact portion 26) is coupled to the other end of the fourth leg portion 24 in the Y direction. Therefore, the cut line C8 that separates the second leg portion 22 and the first region 26a in the Y direction is formed at a boundary between the second leg portion 22 and the second contact portion 26 except for a boundary between the other end of the second leg portion 22 and the one end of the second contact portion 26. In addition, the cut line C9 that separates the fourth leg portion 24 and the second region 26b in the Y direction is formed at a boundary between the fourth leg portion 24 and the second contact portion 26 except for a boundary between the other end of the fourth leg portion 24 and the one end of the second region 26b. Accordingly, the other end of the second leg portion 22 and the one end of the second contact portion 26, and the other end of the fourth leg portion 24 and the other end of the second contact portion 26 are coupled without being separated.

The third region 26c is formed outside the one end of the second leg portion 22, the other end of the beam portion 20, and the one end of the fourth leg portion 24 in the X direction and formed in a strip shape extending in the Y direction. The cut line C10 is formed at a boundary extending in the Y direction between the third region 26c, and each of the one end of the second leg portion 22, the other end of the beam portion 20, and the one end of the fourth leg portion 24. Therefore, the cut lines C8 to C10 form one cut line in a "U" shape.

In this example, a shape of the cell substrate portion 11a in which the units are formed as described above, in plan view, is line-symmetric with a center line in the Y direction of the cell substrate portion 11a as a symmetric axis, and is line-symmetric with a center line in the X direction as a symmetric axis.

An insulating region 21a is provided between the one end and the other end of the first leg portion 21, in this example, approximately at the center of the first leg portion 21 in the longitudinal direction. The insulating region 21a is formed as a region on the base film 15 at which no metal layer 16 is present, and electrically separates the metal layer 16 in the first leg portion 21. That is, in the first leg portion 21, the metal layer 16 is electrically separated into one end side and the other end side by the insulating region 21a. Similar to the first leg portion 21, the second leg portion 22 to the fourth leg portion 24 are provided with insulating regions 22a to 24a at substantially a center thereof in the longitudinal direction. By the insulating regions 21a to 24a, the metal layer 16 is electrically divided into a beam portion region coupled to the beam portion 20, a first heat source-side region coupled to the first contact portion 25, and a second heat source-side region coupled to the second contact portion 26.

A method of forming the insulating regions 21a to 24a is not particularly limited. For example, when the insulating regions 21a to 24a are formed by etching the metal layer 16, or when the metal layer 16 is formed on a surface of the base film 15 by vapor deposition, plating, or the like, the metal layer 16 may not be formed by masking portions serving as the insulating regions 21a to 24a. In addition, a metal thin film having no portions serving as the insulating regions 21a to 24a may be attached to the base film 15 as the metal layer 16.

The thermoelectric element Gp is a p-type thermoelectric element, and the thermoelectric element Gn is an n-type thermoelectric element. In this example, two thermoelectric elements Gp are arranged across the insulating regions 21a and 23a, are soldered to the metal layer 16 (beam portion region) on one end side and the metal layer 16 (first heat source-side region) on the other end side of the first leg portion 21 and the third leg portion 23, respectively, and are mounted on the first leg portion 21 and the third leg portion 23. In addition, two thermoelectric elements Gn are arranged across the insulating regions 22a and 24a, are soldered to the metal layer 16 (beam portion region) on one end side and the metal layer 16 (second heat source-side region) on the other end side of the second leg portion 22 and the fourth leg portion 24, respectively, and are mounted on the second leg portion 22 and the fourth leg portion 24. In this way, the thermoelectric elements Gp and Gn are mounted on the flat plate-shaped wiring substrate 11, and thus the thermoelectric elements Gp and Gn can be easily mounted.

By connecting the thermoelectric elements Gp and Gn as described above, the two thermoelectric elements Gp connected in parallel and the two thermoelectric elements Gn connected in parallel are connected in series in one power generation cell 12. When a temperature of the other ends of the first leg portion 21 to the fourth leg portion 24 is made higher than that of the one ends of the first leg portion 21 to the fourth leg portion 24, the thermoelectric elements Gp and Gn generate an electromotive force in which the first contact portion 25 is a positive electrode and the second contact portion 26 is a negative electrode.

It is preferred that attachment positions of the thermoelectric elements Gp and Gn, that is, formation positions of the insulating regions 21a to 24a, are located in flat portions rather than in curved portions of the first leg portion 21 to the fourth leg portion 24. Accordingly, the thermoelectric elements Gp and Gn can be prevented from dropping. In addition, from the viewpoint of increasing a temperature difference between both ends of the thermoelectric elements Gp and Gn by separating the thermoelectric elements Gp and Gn from the heat source surface Hs, it is preferred to provide the thermoelectric elements Gp and Gn at positions away from the other ends and close to the one ends of the first leg portion 21 to the fourth leg portion 24.

The first contact portion 25 and the second contact portion 26 of the cell substrate portion 11a are moved in directions away from each other, that is, the first contact portion 25 is moved to a left side and the second contact portion 26 is moved to a right side in FIG. 2, and the cell substrate portion 11a is pulled in the X direction so as to increase an interval between the first contact portion 25 and the second contact portion 26, whereby the power generation cell 12 is made three-dimensional.

When the cell substrate portion 11a is pulled as described above, a force is applied to the other ends of the first leg portion 21 and the third leg portion 23 and the other ends of the second leg portion 22 and the fourth leg portion 24 in a direction to increase an interval therebetween. On the other hand, the one ends of the first leg portion 21 and the third leg portion 23 are coupled to the one end of the beam portion 20, and the one ends of the second leg portion 22 and the fourth leg portion 24 are coupled to the other end of the beam portion 20. Therefore, when the above force is applied to the other ends of the first leg portion 21 to the fourth leg portion 24, a pulling force is generated between the one ends of the first leg portion 21 and the third leg portion 23 and the one ends of the second leg portion 22 and the fourth leg portion 24 via the beam portion 20. As a result, the first leg portion 21 to the fourth leg portion 24 are erected, and the beam portion 20 is floated. For example, by placing the wiring substrate 11 on a flat plate and pulling both ends of the wiring substrate 11, the beam portion 20 can be moved upward (in a direction opposite to the flat plate) to make all the power generation cells 12 three-dimensional.

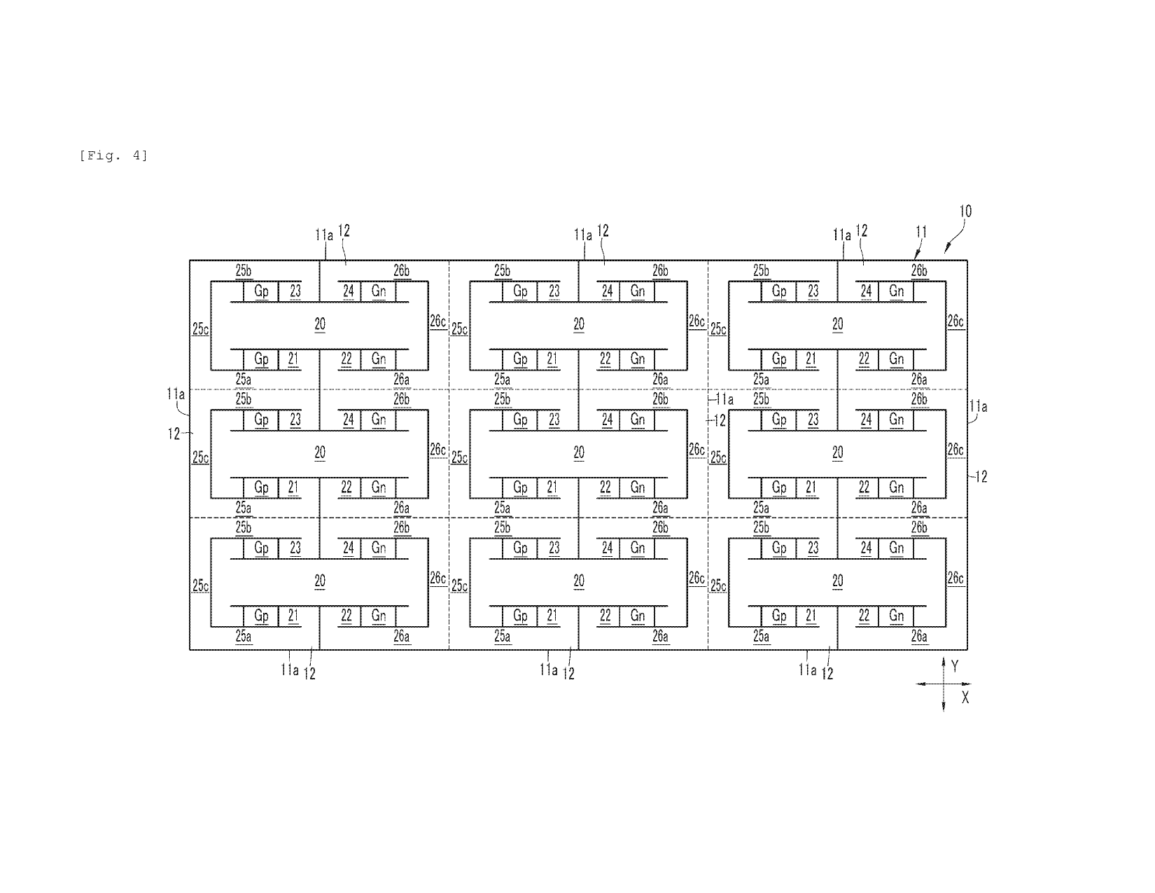

As illustrated in FIG. 3, in the three-dimensional power generation cell 12, the first leg portion 21 and the third leg portion 23 are erected from the other ends coupled to the first contact portion 25, and the second leg portion 22 and the fourth leg portion 24 are erected from the other ends coupled to the second contact portion 26. The beam portion 20 whose both ends are coupled to the one ends of the first leg portion 21 and the third leg portion 23 and the one ends of the second leg portion 22 and the fourth leg portion 24 is disposed at a position higher than positions of the other ends of the first leg portion 21 to the fourth leg portion 24 or the first contact portion 25 and the second contact portion 26. The beam portion 20 in a state in which the power generation cell 12 is made three-dimensional is curved or twisted depending on an attachment state of the first contact portion 25 and the second contact portion 26 to the heat source surface Hs, and a degree of the bending or twisting is also changed.

In the thermoelectric generator 10 in a plan view in a non three-dimensional state as illustrated in FIG. 4, three cell substrate portions 11a are coupled in each of the X direction and the Y direction, and the power generation cells 12 are arranged in a matrix of three rows and three columns. In the cell substrate portions 11a adjacent to each other in the X direction (row direction), the third region 25c of the first contact portion 25 in one cell substrate portion 11a and the third region 26c of the second contact portion 26 in the other cell substrate portion 11a are coupled and integrated. Accordingly, three power generation cells 12 are connected in series in the X direction.

In the cell substrate portions 11a adjacent to each other in the Y direction (column direction), the first region 25a of the first contact portion 25 in one cell substrate portion 11a and the second region 25b of the first contact portion 25 in the other cell substrate portion 11a are coupled and integrated, and the first region 26a of the second contact portion 26 in the one cell substrate portion 11a and the second region 26b of the second contact portion 26 in the other cell substrate portion 11a are coupled and integrated. Accordingly, the three power generation cells 12 are connected in parallel in the Y direction. The first contact portion 25 and the second contact portion 26 at both ends of the thermoelectric generator 10 in the X direction also function as a pair of electrodes for extracting electric power from the thermoelectric generator 10.

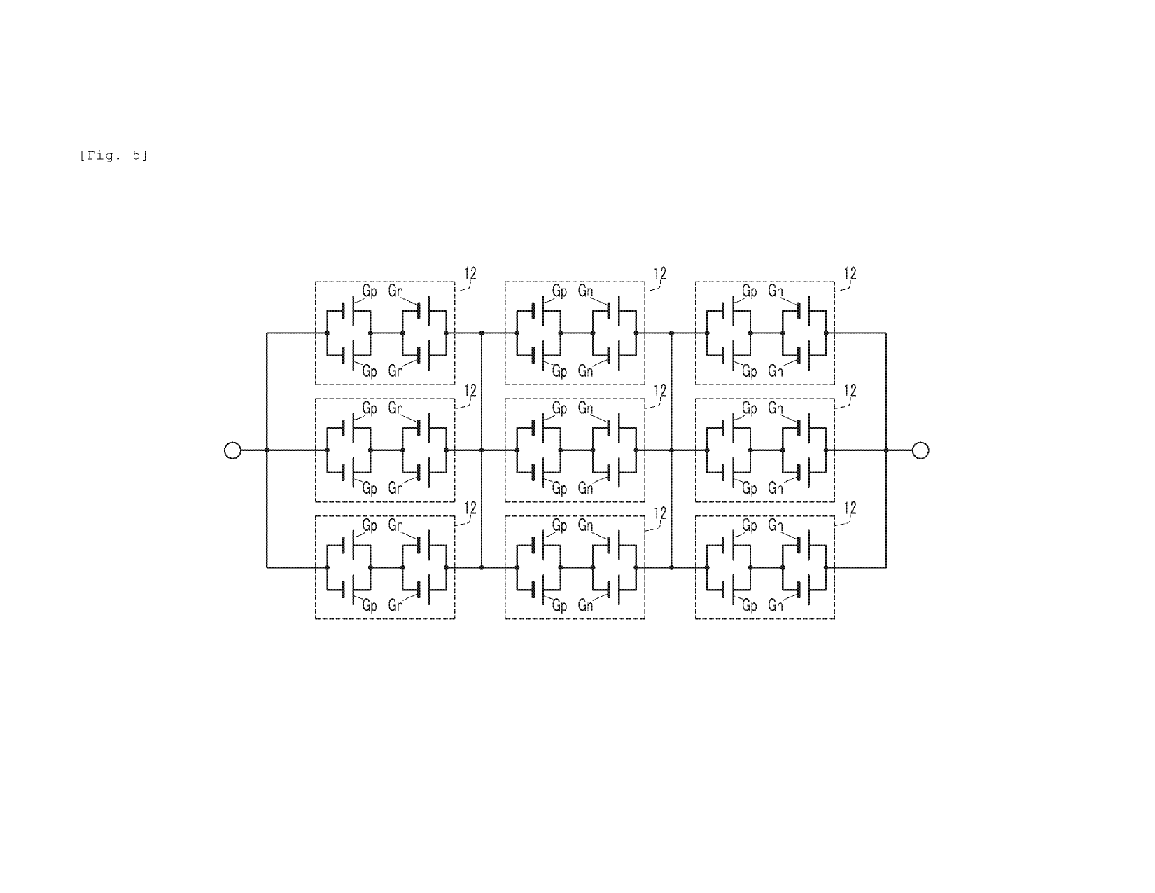

As illustrated in FIG. 5, the thermoelectric generator 10 to which the power generation cells 12 are connected as described above constitutes a circuit in which three power generation cells 12 connected in parallel are connected in series in three sets. Here, assuming that the thermoelectric elements Gp and Gn connected in series are one unit circuit, in one power generation cell 12, two unit circuits are connected in parallel, and in the entire thermoelectric generator 10, six unit circuits are connected in parallel, and six unit circuits are connected in series in three sets.

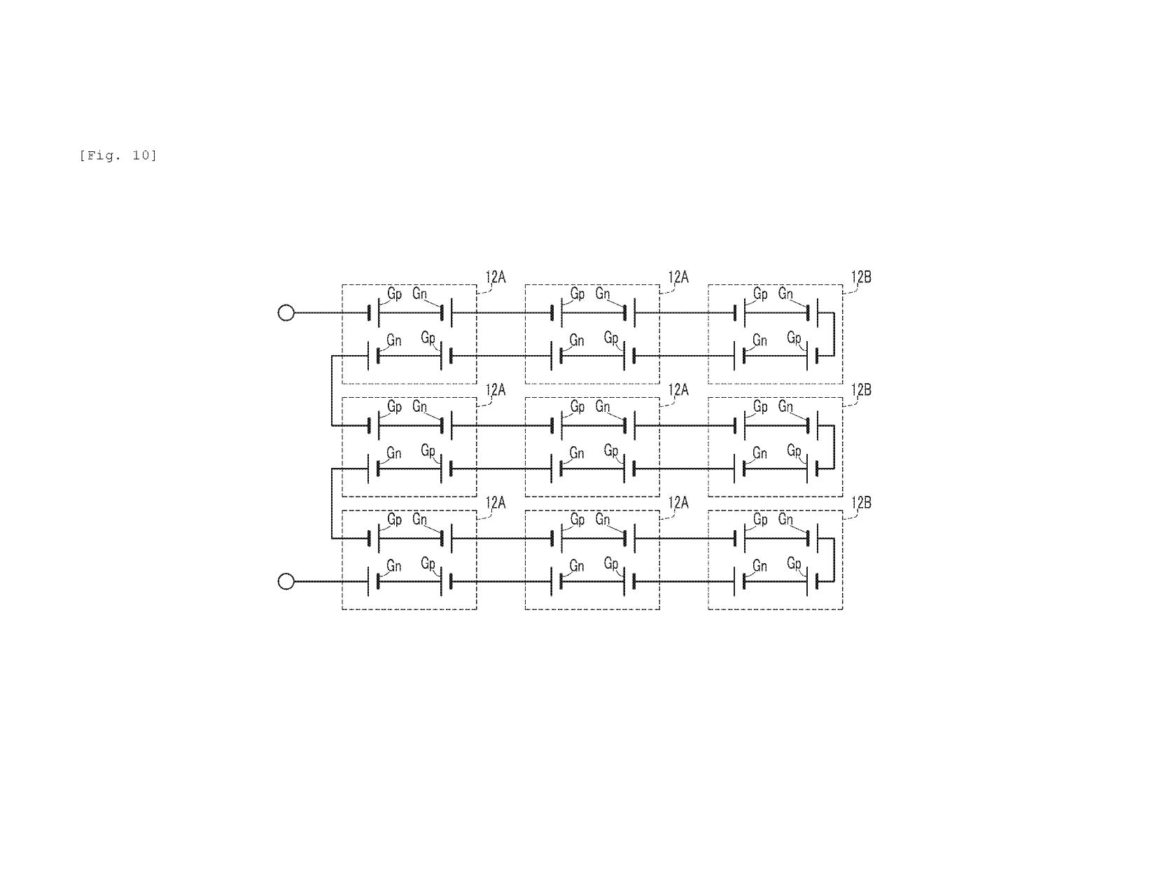

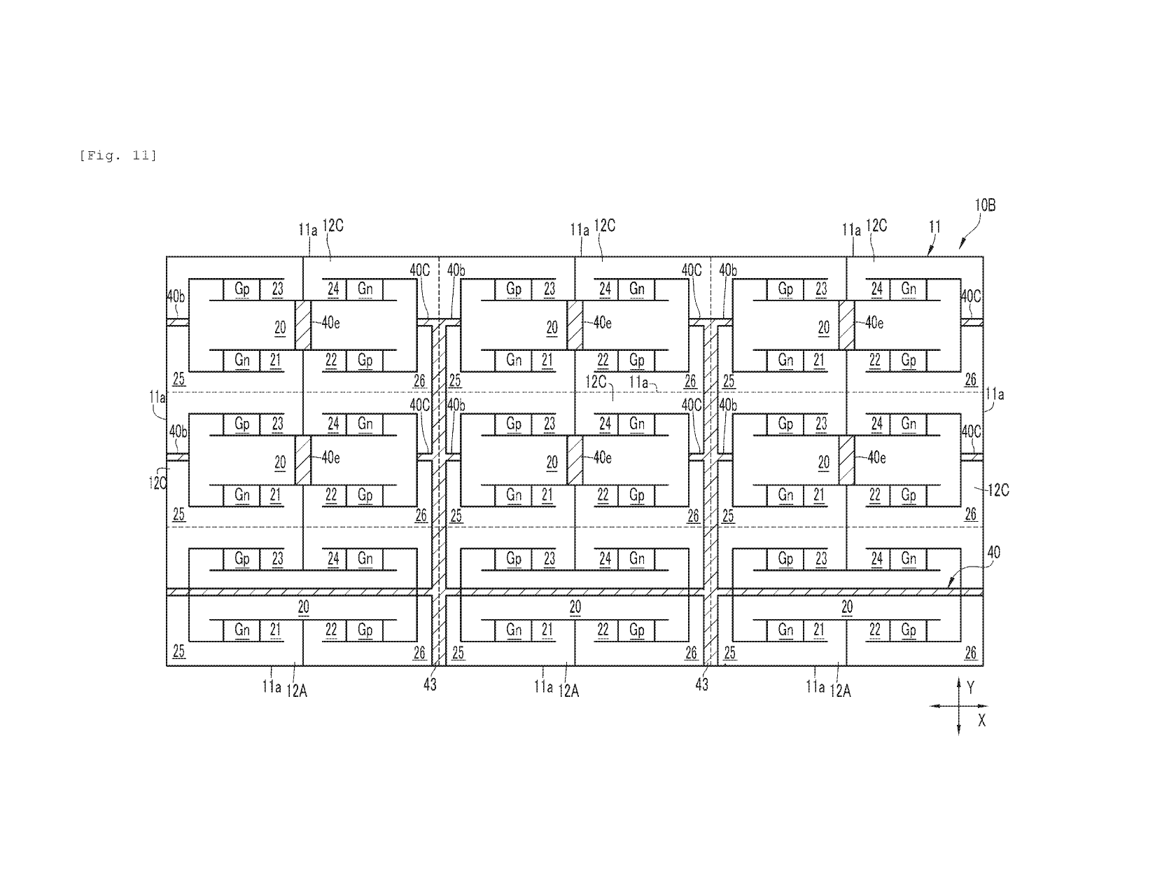

FIG. 5 illustrates the thermoelectric elements Gp and Gn using battery circuit symbols for convenience, and in this circuit symbol, a relatively high temperature side of the thermoelectric element Gp is a positive electrode, a relatively low temperature side of the thermoelectric element Gp is a negative electrode, a relatively high temperature side of the thermoelectric element Gn is a negative electrode, and a relatively low temperature side of the thermoelectric element Gn is a positive electrode. FIGS. 10 and 12 also illustrate the thermoelectric elements Gp and Gn using battery circuit symbols for convenience.

When the thermoelectric generator 10 is attached to the heat source surface Hs, both ends of the wiring substrate 11 in the X direction are pulled. Due to this pulling, a pulling force is applied to each of the cell substrate portions 11a formed on the wiring substrate 11 in directions in which the first contact portion 25 and the second contact portion 26 are separated from each other. As a result, each of the power generation cells 12 formed on the wiring substrate 11 is simultaneously formed into a three-dimensional shape. Therefore, it is not necessary to perform an operation for individually making the plurality of power generation cells 12 provided in the thermoelectric generator 10 three-dimensional, and it is easy to make the power generation cells 12 of the thermoelectric generator 10 three-dimensional.

The three-dimensional thermoelectric generator 10 is attached to the heat source surface Hs by, for example, attaching lower surfaces (surfaces opposite to the metal layer 16) of the first contact portions 25 and the second contact portions 26 in close contact with the heat source surface Hs.

In the thermoelectric generator 10, the metal layer 16 mainly performs heat conduction, and heat from the heat source surface Hs is transmitted to one ends of the thermoelectric elements Gp and Gn from the first contact portion 25 and the second contact portion 26 through the metal layer 16 on the other end sides of the first leg portion 21 to the fourth leg portion 24 to increase the temperature of the one ends of the thermoelectric elements Gp and Gn. In addition, the heat from the thermoelectric elements Gp and Gn is dissipated in the beam portion 20 through the metal layer 16 on the one end sides of the first leg portion 21 to the fourth leg portion 24, so that the temperature of the other ends of the thermoelectric elements Gp and Gn is effectively lowered. In this way, the temperature difference is generated between the thermoelectric elements Gp and Gn, and an electromotive force generated in the thermoelectric generator 10 is extracted from the first contact portion 25 and the second contact portion 26 at both ends in the X direction. As described above, the thermoelectric generator 10 in this example is a circuit in which parallel circuits each having six unit circuits are connected in series in three sets, and thus six times a current and three times a voltage can be obtained, resulting in 18 times the electric power as compared with a case in which one unit circuit is used.

The beam portion 20 is floated by the first leg portion 21 to the fourth leg portion 24, and thus the beam portion 20 to be a low-temperature source can be largely separated from the heat source surface Hs, thereby obtaining a high power generation efficiency. Further, the thermoelectric elements Gp and Gn are disposed far above the heat source surface Hs, and thus higher power generation efficiency can be obtained.

The thermoelectric generator 10 has the above structure, and thus has a degree of freedom that allows the wiring substrate 11 to be deformed without applying a force that causes the thermoelectric elements Gp and Gn to fall off, and has a great degree of freedom in the shape of the heat source surface Hs that can be attached. Therefore, the thermoelectric generator 10 can be attached to a curved surface, such as a cylindrical surface or a spherical surface, and the high power generation efficiency can be obtained.

By forming an insulating region (hereinafter, referred to as a connection pattern insulating region) for defining a connection pattern in the metal layer 16 in the power generation cell 12 separately from the insulating regions 21a to 24a, a connection mode of the thermoelectric elements Gp and Gn in the power generation cell 12 can be variously changed. Hereinafter, when the thermoelectric element Gp and the thermoelectric element Gn are not distinguished from each other, they are described as the thermoelectric element G.

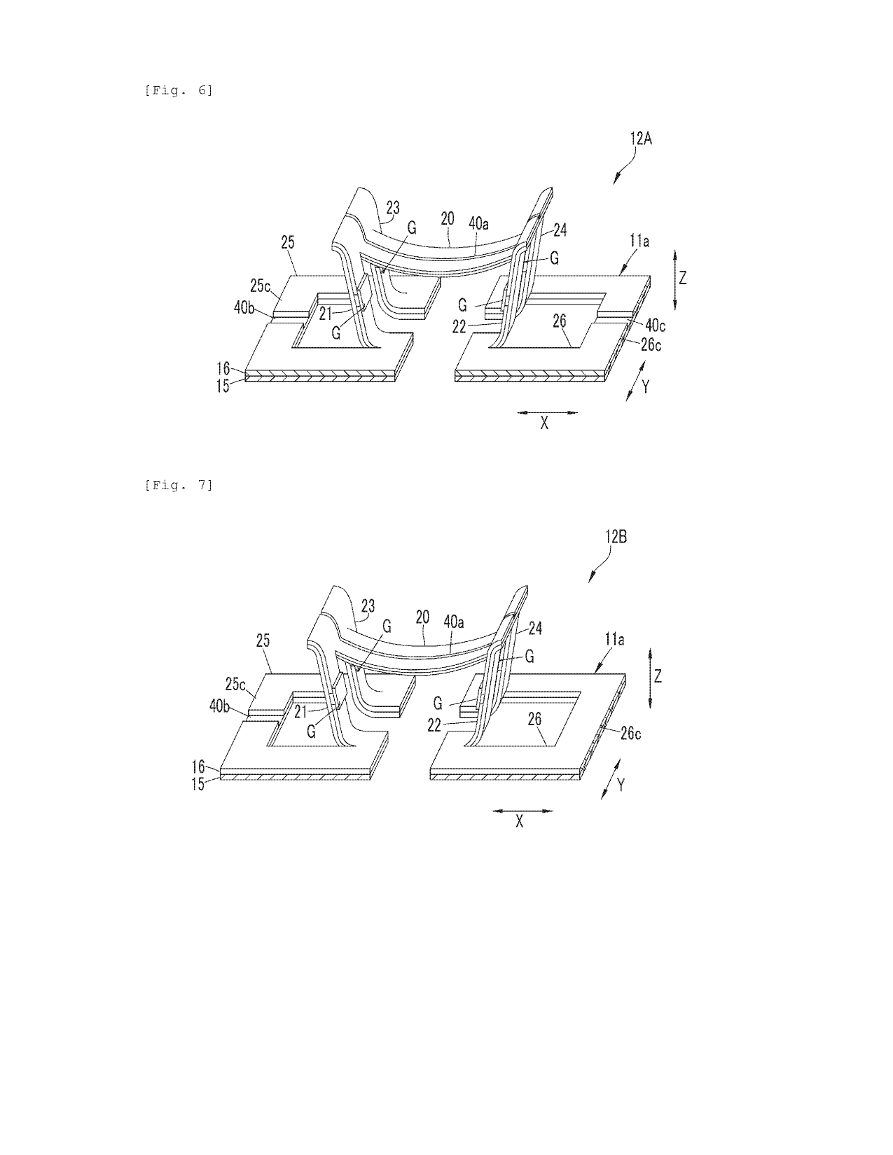

A power generation cell 12A illustrated in FIG. 6 includes two unit circuits electrically separated from each other. Specifically, the thermoelectric element G provided in the first leg portion 21 and the thermoelectric element G provided in the second leg portion 22 are connected in series to form one unit circuit, and separately, the thermoelectric element G provided in the third leg portion 23 and the thermoelectric element G provided in the fourth leg portion 24 are connected in series to form a unit circuit, and the unit circuits are electrically separated by connection pattern insulating regions 40a to 40c.

The connection pattern insulating region 40a extends in the X direction of the beam portion 20 so as to pass through the center of the beam portion 20 in the width direction, and electrically separates the metal layers 16 on the one end sides of the first leg portion 21 and the third leg portion 23. The connection pattern insulating region 40b is formed in the third region 25c of the first contact portion 25, and electrically separates the metal layer 16 of the first contact portion 25 into the other end side of the first leg portion 21 and the other end side of the third leg portion 23. Similarly, the connection pattern insulating region 40c is formed in the third region 26c of the second contact portion 26, and electrically separates the metal layer 16 of the second contact portion 26 into the other end side of the second leg portion 22 and the other end side of the fourth leg portion 24. In the power generation cell 12A, the first leg portion 21 and the third leg portion 23 may be provided with thermoelectric elements G of different types (p-type or n-type), and similarly, the second leg portion 22 and the fourth leg portion 24 may be provided with thermoelectric elements G of different types.

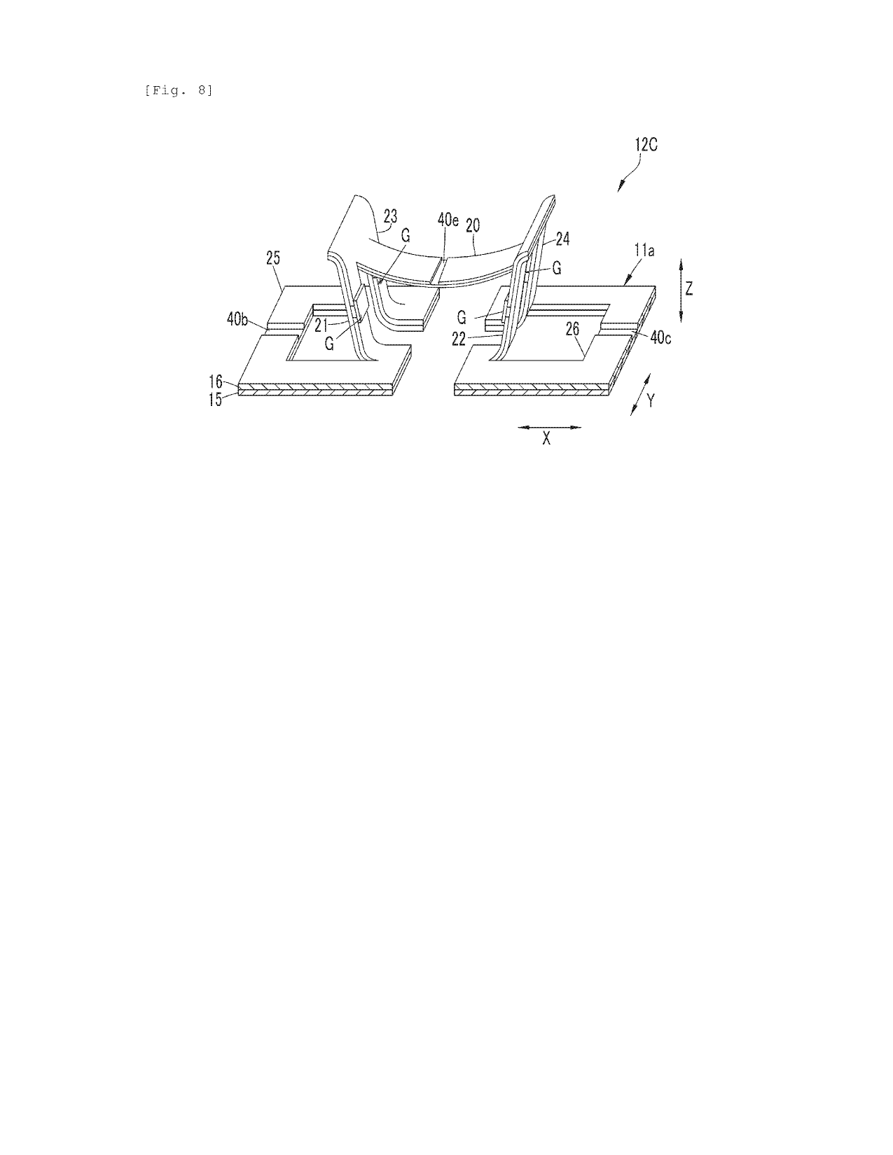

A power generation cell 12B illustrated in FIG. 7 is configured such that two unit circuits are connected in series. The power generation cell 12B is the same as the power generation cell 12A illustrated in FIG. 6 except that no connection pattern insulating region is provided in the third region 26c of the second contact portion 26. In the power generation cell 12B, the first leg portion 21 and the fourth leg portion 24 are provided with thermoelectric elements G of the same type, and the second leg portion 22 and the third leg portion 23 are provided with thermoelectric elements G of different types from the first leg portion 21 and the fourth leg portion 24. Accordingly, a unit circuit including the thermoelectric element G provided in the first leg portion 21 and the thermoelectric element G provided in the second leg portion 22 and a unit circuit including the thermoelectric element G provided in the third leg portion 23 and the thermoelectric element G provided in the fourth leg portion 24 are connected in series by the second contact portion 26.

A power generation cell 12C illustrated in FIG. 8 forms two electrically separated unit circuits, similar to the power generation cell 12A illustrated in FIG. 6, but each of the thermoelectric elements G of the first leg portion 21 and the third leg portion 23 forms one unit circuit, and each of the thermoelectric elements G of the second leg portion 22 and the fourth leg portion 24 forms one unit circuit. In the power generation cell 12C, a connection pattern insulating region 40e extending in the Y direction is formed at the center of the beam portion 20 in the X direction. Accordingly, the metal layer 16 on the one end sides of the first leg portion 21 and the third leg portion 23, and the one end sides of the second leg portion 22 and the fourth leg portion 24 is electrically separated. The first contact portion 25 is formed with the connection pattern insulating region 40b, and the second contact portion 26 is formed with the connection pattern insulating region 40c. In the power generation cell 12C, the first leg portion 21 and the third leg portion 23 may be provided with the thermoelectric elements G of different types (p-type or n-type), and similarly, the second leg portion 22 and the fourth leg portion 24 may be provided with the thermoelectric elements G of different types.

By combining the power generation cells 12, 12A, 12B, 12C, and the like as described above, the thermoelectric generator can be configured in which the plurality of thermoelectric elements Gp and Gn are connected in various connection modes.

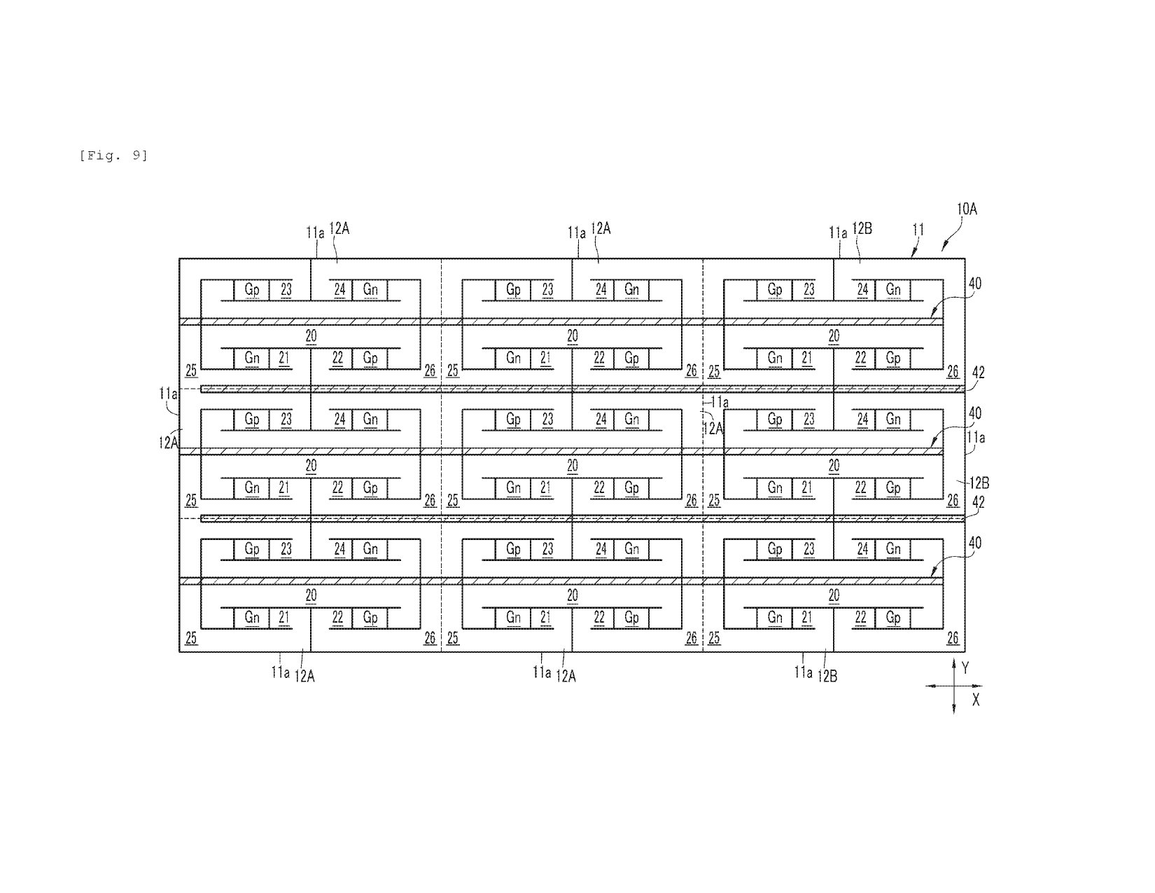

In a thermoelectric generator 10A illustrated in FIG. 9, the power generation cell 12A and the power generation cell 12B are combined, and 18 unit circuits are connected in series. A circuit configuration of the thermoelectric generator 10A is illustrated in FIG. 10. FIG. 9 illustrates a state before the thermoelectric generator 10A is made three-dimensional. Reference numeral 40 denotes a connection pattern insulating region portion including the connection pattern insulating regions 40a to 40c.

In the thermoelectric generator 10A, the power generation cell 12A, the power generation cell 12A, and the power generation cell 12B are arranged in this order in the X direction as one row, and three rows are arranged in the Y direction to be integrated. At boundaries between the rows of the thermoelectric generator 10A, insulating regions 42 are formed by removing the metal layer 16. The insulating region 42 insulates the power generation cells adjacent to each other in the Y direction, but is not formed in a part of a boundary between the first contact portions 25 of the power generation cells 12A adjacent to each other in the Y direction at end portions in the X direction.

In the thermoelectric generator 10A, two series circuits in which three unit circuits are connected in series in one row are connected in series by the second contact portion 26 of the power generation cell 12B. In addition, the series circuits of each row are further connected in series by electrical connection between the first contact portions 25 of the power generation cells 12A adjacent in the Y direction at the end portions in the X direction.

In a thermoelectric generator 10B illustrated in FIG. 11, the power generation cells 12A and the power generation cells 12C are combined to form a circuit in which 15 unit circuits are connected in series. A circuit configuration of the thermoelectric generator 10B is illustrated in FIG. 12. FIG. 11 illustrates a state before the thermoelectric generator 10B is made three-dimensional. In the thermoelectric generator 10B, the power generation cell 12C, the power generation cell 12C, and the power generation cell 12A are arranged in this order in the Y direction as one column, and three columns are arranged in the X direction to be integrated. At boundaries between the columns, the insulating regions 43 are formed by removing the metal layer 16. The insulating region 43 insulates the power generation cells adjacent to each other in the X direction, but is not formed in a part of a boundary between the first contact portion 25 and the second contact portion 26 of the power generation cells 12C adjacent to each other in the X direction at end portions in the Y direction.

In the thermoelectric generator 10B, a series circuit is formed in which five unit circuits are connected in series in one column. In addition, the series circuits of each column are connected in series by electrical connection between the first contact portion 25 and the second contact portion 26 of the power generation cells 12C adjacent in the X direction at the end portions in the Y direction. In the thermoelectric generator 10B, the thermoelectric elements Gp and Gn of the first leg portion 21 and the second leg portion 22 of each of the power generation cells 12A can be omitted.

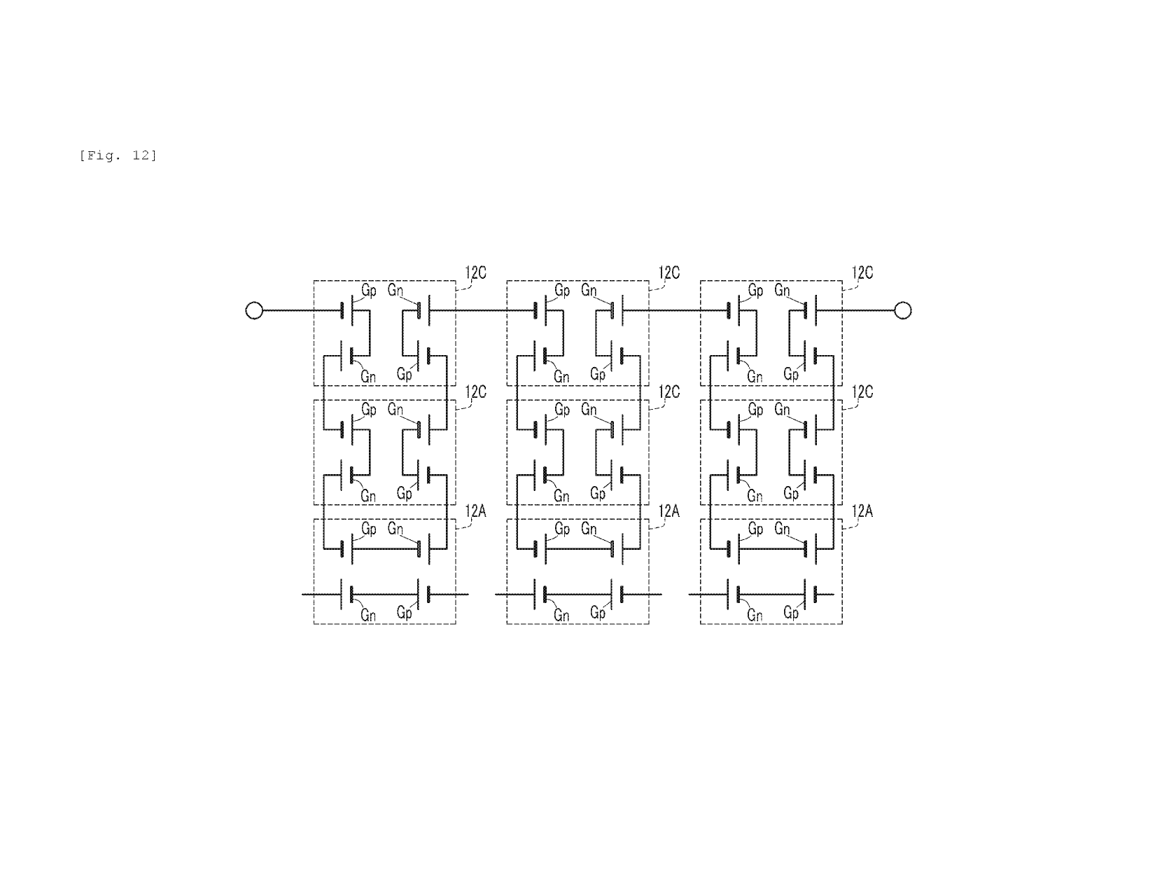

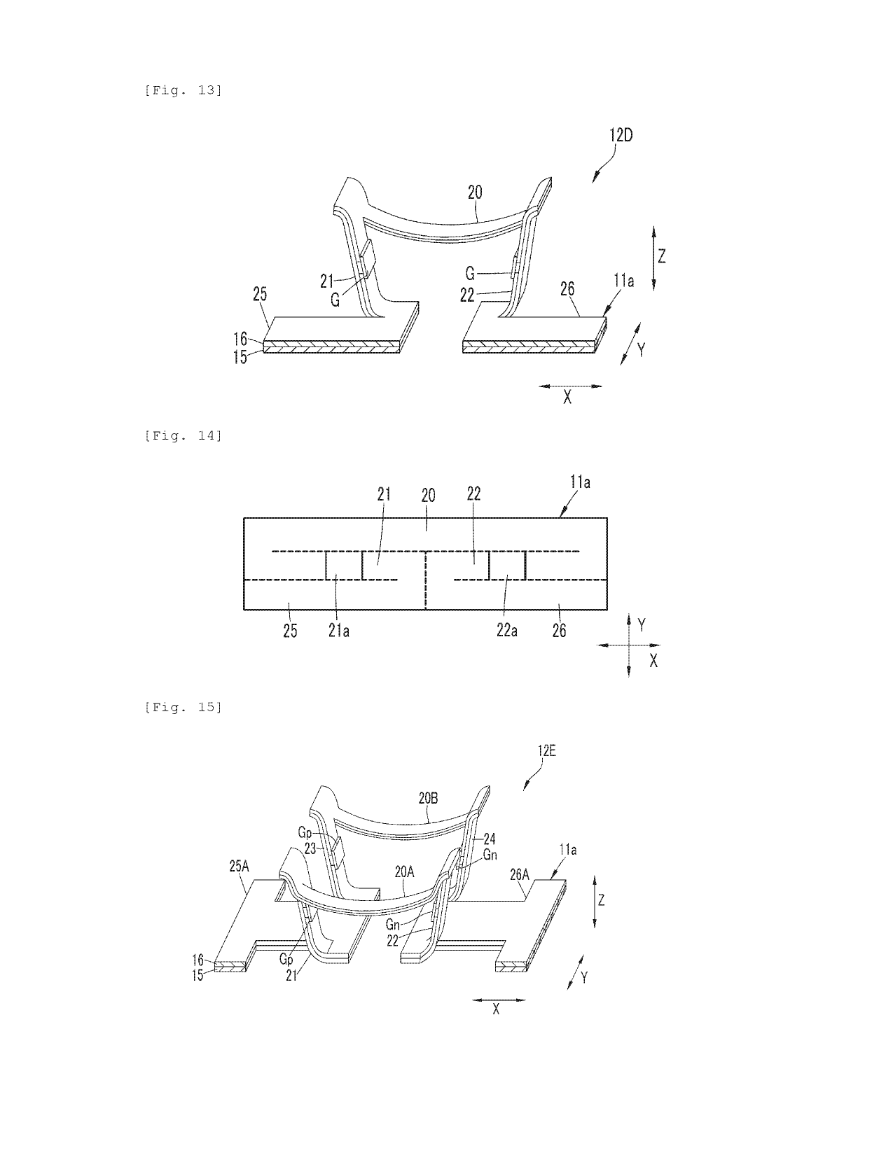

In the above examples, one power generation cell has a four-leg configuration including the first leg portion 21 to the fourth leg portion 24, but may also have a two-leg configuration in which a pair of leg portions (first leg portion 21 and second leg portion 22) are provided on only one side of the beam portion 20, as in a power generation cell 12D illustrated in FIG. 13. FIG. 14 illustrates the flat plate-shaped cell substrate portion 11a before being made three-dimensional, corresponding to the power generation cell 12D, with cut lines indicated by dashed lines. In the power generation cell 12D, both ends of the beam portion 20 are coupled to one sides of the one ends of the first leg portion 21 and the second leg portion 22. The one end of the first contact portion 25 is coupled to the other side of the other end of the first leg portion 21 in a strip shape extending parallel to the first leg portion 21 toward the one end of the first leg portion 21, and the one end of the second contact portion 26 is coupled to the other side of the other end of the second leg portion 22 in a strip shape extending parallel to the second leg portion 22 toward the one end of the second leg portion 22. Such a two-leg configuration is a minimum configuration of the power generation cell that is made three-dimensional by being pulled.

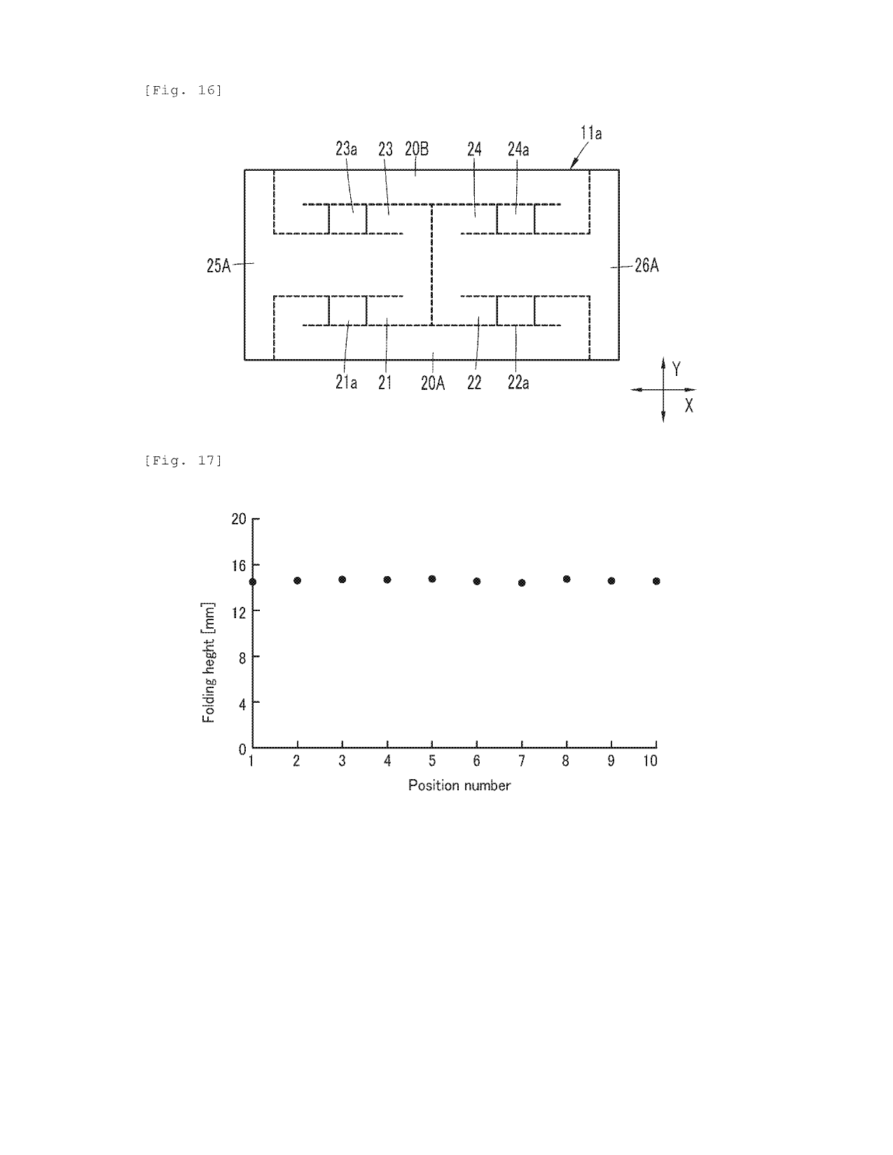

As in the power generation cell 12E illustrated in FIG. 15, two beam portions 20A and 20B may be provided, the one ends of the first leg portion 21 and the second leg portion 22 may be coupled to both ends of the beam portion 20A, and the one ends of the third leg portion 23 and the fourth leg portion 24 may be coupled to both ends of the beam portion 20B. FIG. 16 illustrates the flat plate-shaped cell substrate portion 11a before being made three-dimensional, corresponding to the power generation cell 12E, with cut lines indicated by dashed lines. In the power generation cell 12E, the other end of the first leg portion 21 is coupled to one side portion of the first contact portion 25A, the other end of the third leg portion 23 is coupled to the other side portion of the first contact portion 25A, the other end of the second leg portion 22 is coupled to one side portion of the second contact portion 26A, and the other end of the fourth leg portion 24 is coupled to the other side portion of the second contact portion 26A. The power generation cell 12E has a two-fold symmetric shape. Therefore, with respect to the beam portion 20A, the first leg portion 21 and the second leg portion 22 are coupled to a rear side of the beam portion 20A and a front side of the first contact portion 25A and the second contact portion 26A in FIG. 15, respectively, and with respect to the beam portion 20B, the third leg portion 23 and the fourth leg portion 24 are coupled to a front side of the beam portion 20A and a rear side of the first contact portion 25A and the second contact portion 26A in FIG. 15, respectively. The power generation cell 12E can also be provided with a connection pattern insulating region, as in the power generation cells 12A to 12C.

A thermoelectric generator in which five power generation cells 12 were arranged in the X direction and integrated was prepared, and it was confirmed that the thermoelectric generator was made three-dimensional. A thermoelectric generator on which no thermoelectric elements Gp and Gn are mounted was prepared. Of the prepared thermoelectric generator before being made three-dimensional, the power generation cell 12 had a length in the X direction of 38 mm and a length in the Y direction of 18 mm, the first leg portion 21 to the fourth leg portion 24 had a length in the Y direction of 3 mm, the cut lines C5, C6, C8, and C9 had a length of 13 mm, the beam portion 20 had a length in the Y direction of 7 mm, a portion at which the first leg portion 21 and the third leg portion 23, and the first contact portion 25 are coupled and a portion at which the second leg portion 22 and the fourth leg portion 24, and the second contact portion 26 are coupled each had a length in the X direction of 3 mm, and the third regions 25c and 26c of the first contact portion 25 and the second contact portion 26 each had a length in the X direction of 3 mm. As the wiring substrate 11, a polyimide film having a thickness of 40 μm was used as the base film 15, and a copper foil having a thickness of 50 μm was used as the metal layer 16. When the prepared thermoelectric generator was pulled by 65 mm in the X direction, the first leg portion 21 to the fourth leg portion 24 of each of the power generation cells 12 are erected, and it was confirmed that each of the beam portion 20 is floated.

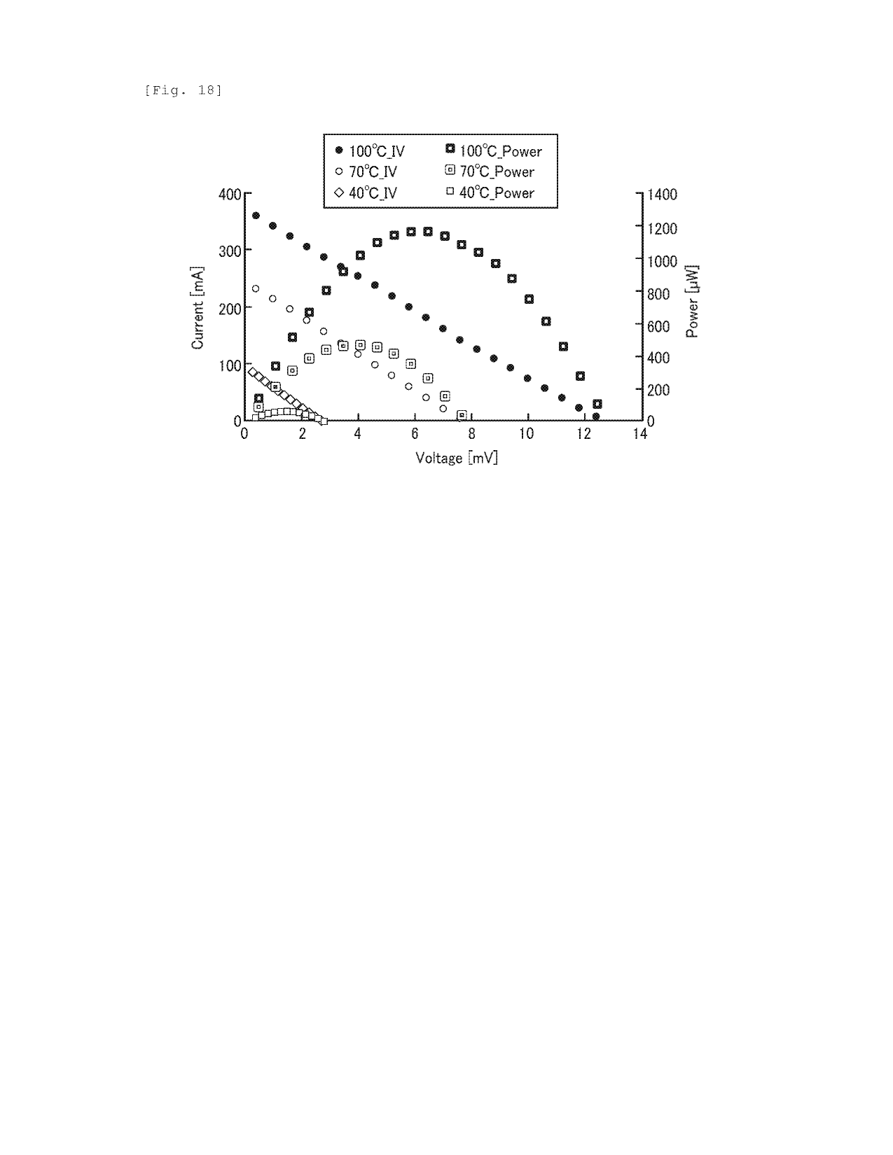

The heights of the one end and the other end of the beam portion 20 provided in each of the power generation cells 12 of the three-dimensional thermoelectric generator as described above were measured. The height of the one end of the beam portion 20 was a height from an end portion of the third region 25c, which is the lowest of the first contact portion 25, and the height of the other end of the beam portion 20 was a height from an end portion of the third region 26c, which is the lowest of the second contact portion 26. Height measurement results are illustrated in FIG. 17. "Position number" on a horizontal axis of the graph in FIG. 17 is a measurement number of the one end and the other end of the beam portion 20 given in order from one end to the other end of the thermoelectric generator. It was confirmed from this result that each of the power generation cells 12 was uniformly deformed and made three-dimensional.

A power generation amount was measured for one power generation cell 12. The power generation cell 12 has the same size as that of the power generation cell 12 of the thermoelectric generator. The thermoelectric element Gp was made of BiO₃Sb_{1.7}Te₃, and the thermoelectric element Gn was made of Bi₂Te₃ + Ru. Each of the thermoelectric elements Gp and Gn had a size of 4 mm × 3 mm × 1 mm (length in the X direction × length in the Y direction × length in the Z direction). The prepared power generation cell 12 had an electrical resistance of 28.5 mΩ. In a room at which the room temperature was maintained at 22°C, the first contact portion 25 and the second contact portion 26 were attached to the heat source surface Hs. At this time, the interval between the first contact portion 25 and the second contact portion 26 was set to 13 mm, and the power generation cell 12 was made three-dimensional. The power generation amount of the power generation cell 12 was measured when the temperature of the heat source surface Hs was set to 40°C, 70°C, and 100°C. Measurement results are illustrated in FIG. 18. When the temperature of the heat source surface Hs was set to 40°C, 70°C, and 100°C, a maximum power generation capacity was 63.36 μW, 469.1 μW, and 1,162 μW, respectively, and an open-circuit voltage was 2.82 mV, 7.62 mV, and 12.6 mV, respectively, confirming that the power generation is efficient.

### Reference Signs List

10, 10A, 10B: thermoelectric generator

11: wiring substrate

11a: cell substrate portion

12, 12A, 12B, 12C, 12D, 12E: power generation cell

20, 20A, 20B: beam portion

21: first leg portion

22: second leg portion

23: third leg portion

24: fourth leg portion

25, 25A: first contact portion

26, 26A: second contact portion

G, Gn, Gp: thermoelectric element

1. A thermoelectric generator substrate comprising:
a flexible substrate including a sheet-shaped insulating base material and a metal layer formed on one surface of the base material; and
a cell substrate portion formed on the flexible substrate, wherein
the cell substrate portion includes
a strip-shaped first beam portion,
a strip-shaped first leg portion whose one end is coupled to one end of the first beam portion in a width direction and extends parallel to the first beam portion toward a center of the first beam portion,
a strip-shaped second leg portion whose one end is coupled to the other end of the first beam portion in the width direction and extends parallel to the first beam portion toward the center of the first beam portion,
a first contact portion coupled to the other end of the first leg portion in the width direction on a side opposite to the first beam portion and in contact with a heat source, and a second contact portion coupled to the other end of the second leg portion in the width direction on a side opposite to the first beam portion and in contact with the heat source, and
the first leg portion and the second leg portion are configured to deform and erect such that the one end of the first leg portion and the one end of the second leg portion move in a direction away from the first contact portion and the second contact portion together with the first beam portion in a thickness direction of the substrate by widening an interval between the first contact portion and the second contact portion.

2. The thermoelectric generator substrate according to claim 1, wherein
the cell substrate portion includes
a strip-shaped third leg portion whose one end is coupled to the one end of the first beam portion on a side opposite to the first leg portion in the width direction and extends parallel to the first beam portion toward the center of the first beam portion, and
a strip-shaped fourth leg portion whose one end is coupled to the other end of the first beam portion on a side opposite to the second leg portion in the width direction and extends parallel to the first beam portion toward the center of the first beam portion,
the first contact portion is coupled to the other end of the third leg portion,
the second contact portion is coupled to the other end of the fourth leg portion, and
the third leg portion and the fourth leg portion are configured to deform and erect such that the one end of the third leg portion and the one end of the fourth leg portion, together with the first leg portion and the second leg portion, move in a direction away from the first contact portion and the second contact portion together with the first beam portion in the thickness direction of the substrate by widening the interval between the first contact portion and the second contact portion.

3. The thermoelectric generator substrate according to claim 1, wherein
the cell substrate portion includes
a strip-shaped second beam portion,
a strip-shaped third leg portion whose one end is coupled to one end of the second beam portion in the width direction and extends parallel to the second beam portion toward a center of the second beam portion, and the other end is coupled to the first contact portion on a side opposite to the first leg portion in the width direction, and
a strip-shaped fourth leg portion whose one end is coupled to the other end of the second beam portion in the width direction and extends parallel to the second beam portion toward the center of the second beam portion, and the other end is coupled to the second contact portion on a side opposite to the second leg portion in the width direction,
the one end of the third leg portion is coupled to the second beam portion on a side opposite to the first contact portion in the width direction,
the one end of the fourth leg portion is coupled on a side opposite to the second contact portion in the width direction and on the same side as the second beam portion to which the third leg portion of the second beam portion is coupled, and
the third leg portion and the fourth leg portion are configured to deform and erect such that the one end of the third leg portion and the one end of the fourth leg portion, together with the first leg portion and the second leg portion, move in a direction away from the first contact portion and the second contact portion together with the second beam portion in the thickness direction of the substrate by widening the interval between the first contact portion and the second contact portion.

4. The thermoelectric generator substrate according to claim 2, wherein
a plurality of the cell substrate portions coupled in an extending direction of the first beam portion are formed, and the first contact portion of one of the cell substrate portions and the second contact portion of another one of the cell substrate portions are coupled.

5. The thermoelectric generator substrate according to claim 3, wherein
a plurality of the cell substrate portions coupled in an extending direction of the first beam portion are formed, and the first contact portion of one of the cell substrate portions and the second contact portion of another one of the cell substrate portions are coupled.

6. A thermoelectric generator comprising:
the thermoelectric generator substrate according to claim 4;
a first thermoelectric element provided in each of the first leg portions;
a second thermoelectric element provided in each of the second leg portions;
a third thermoelectric element provided in each of the third leg portions; and
a fourth thermoelectric element provided in each of the fourth leg portions.

7. A thermoelectric generator comprising:
the thermoelectric generator substrate according to claim 5;
a first thermoelectric element provided in each of the first leg portions;
a second thermoelectric element provided in each of the second leg portions;
a third thermoelectric element provided in each of the third leg portions; and
a fourth thermoelectric element provided in each of the fourth leg portions.
